(19) United States
(12) Patent Application Publication
(10) Pub. No.: US 2005/0036357 A1
(43) Pub. Date: Feb. 17, 2005

(54) Digital signal processor having a programmable address generator, and applications thereof

(75) Inventors: Hoang Nhu, Irvine, CA (US); Jeffrey S. Bauch, Alpharetta, GB (US)

Correspondence Address: STERNE, KESSLER, GOLDSTEIN & FOX PLLC, 1100 NEW YORK AVENUE, N.W., WASHINGTON, DC, 20005, US

(73) Assignee: Broadcom Corporation

(21) Appl. No.: 10/641,295

(22) Filed: Aug. 15, 2003

(51) Int. Cl. G11C 11/00

(52) U.S. Cl. 365/133

(57) ABSTRACT

A digital signal processor having a programmable address generator. In an embodiment, the programmable address generator enables an execution unit of the digital signal processor to perform register addressing, indirect addressing, and immediate addressing in response to a single arithmetic instruction. The digital signal processor is useful for implementing, for example, reprogrammable decoders and digital filters. In one embodiment, the digital signal processor is used to implement a US/Japan BTSC decoder.

### FIELD OF THE INVENTION

The present invention relates generally to digital signal processing and applications thereof.

### BACKGROUND OF THE INVENTION

Digital signal processing (DSP) is used in many applications such as, for example, control and communication applications. In many of these applications, special application DSP integrated circuits are used. While these special application DSP integrated circuits are useful for their intended special applications, they typically lack reprogrammability features and flexible operating instructions that would make them adaptable and/or updateable. These limitations are due, at least in part, to the limited addressing capabilities of available DSP integrated circuits and their operating instructions.

What is needed is a DSP integrated circuit that overcomes the reprogramability and operating instruction limitations of available DSP integrated circuits.

### BRIEF SUMMARY OF THE INVENTION

The present invention provides a digital signal processor having an execution unit, an address generator, and an instruction set. The programmable address generator enables the execution unit to perform register addressing, indirect addressing, and immediate addressing. In an embodiment, the programmable address generator enables the execution unit to perform register addressing, indirect addressing, and immediate addressing in response to a single arithmetic instruction of the instruction set.

The digital signal processor includes or is coupled to memory. In an embodiment, the digital signal processor includes or is coupled to both random-access memory and read-only memory.

In an embodiment, the digital signal processor includes both execution registers and address registers. In an embodiment, the address registers include at least one register for storing a random-access memory base address value and at least one register for storing a random-access memory offset address value. In an embodiment, the address registers include at least one register for reading a read-only memory base address value and at least one register for reading a read-only memory offset address value.

In an embodiment, the instruction set of the digital signal processor includes at least one address register load instruction and at least one arithmetic instruction that performs both multiplication and addition operations. In an embodiment, the instruction set includes an instruction that performs both multiplication and subtraction operations. In an embodiment, the instruction set includes at least one instruction that indexes a lookup table.

It is a feature and advantage of the digital signal processor of the present invention that it can be used to implement, for example, reprogrammable and updateable digital decoders and digital filters. In an embodiment, the digital signal processor of the present invention is used to implement a versatile US/Japan Broadcast Television System Committee (BTSC) decoder.

Further features and advantages of the present invention, as well as the structure and operation of various embodiments of the present invention, are described in detail below with reference to the accompanying drawings.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the pertinent art to make and use the invention.

FIG. 1 illustrates a block diagram of a digital signal processor according to the present invention.

FIG. 2 illustrates a first example instruction for the digital signal processor of FIG. 1.

FIG. 3 illustrates a second example instruction for the digital signal processor of FIG. 1.

FIG. 4 illustrates a third example instruction for the digital signal processor of FIG. 1.

FIG. 5A illustrates a BTSC decoder that uses the digital signal processor of the present invention.

FIG. 5B illustrates an example instruction set for the BTSC decoder of FIG. 5A.

FIG. 6 illustrates an equation used to implement a first-order infinite impulse response filter.

FIG. 7 illustrates an equation used to implement a second-order infinite impulse response filter.

FIG. 8 illustrates a first example instruction for the BTSC decoder of FIG. 5A.

FIG. 9 illustrates a second example instruction for the BTSC decoder of FIG. 5A.

FIG. 10 illustrates a third example instruction for the BTSC decoder of FIG. 5A.

FIG. 11 illustrates the operation of the instructions of FIG. 8 and FIG. 9.

FIG. 12 illustrates the operation of the instruction of FIG. 10.

FIG. 13 illustrates an example program code segment for the BTSC decoder of FIG. 5A.

### DETAILED DESCRIPTION OF THE INVENTION

Overview of the Invention

The present invention relates to a digital signal processor having a programmable address generator. The programmable address generator enables an execution unit of the digital signal processor to perform register addressing, indirect addressing, and immediate addressing. In an embodiment, the programmable address generator enables the execution unit to perform register addressing, indirect addressing, and immediate addressing in response to a single arithmetic instruction. The digital signal processor is useful for implementing, for example, reprogrammable decoders and digital filters. In one embodiment, the digital signal processor is used to implement a US/Japan BTSC decoder.

Example Digital Signal Processor According to the Present Invention

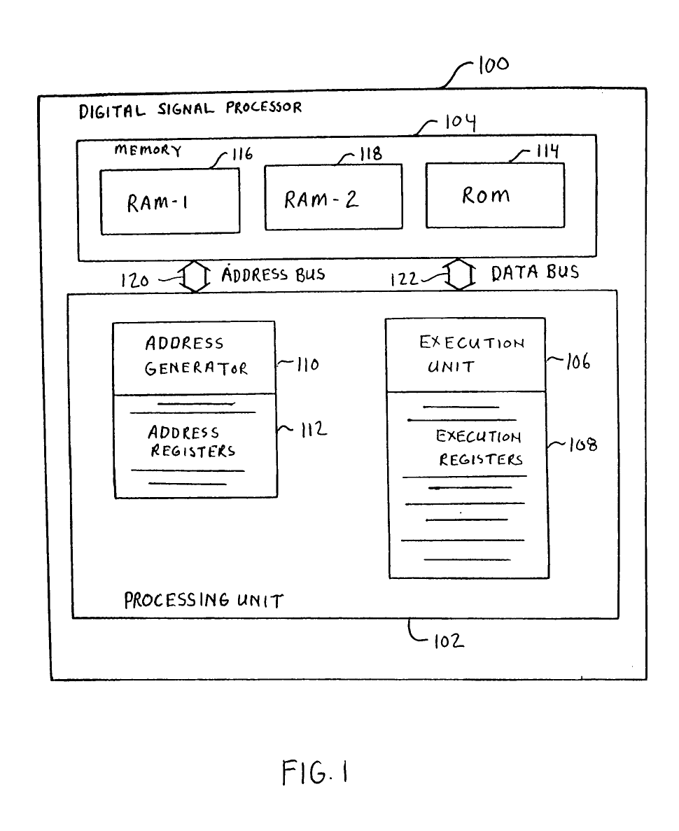

FIG. 1 illustrates a block diagram of an example digital signal processor 100 according to the present invention. Digital signal processor 100 includes a processing unit 102 and a memory 104. Processing unit 102 and memory 104 are connected by an address bus 120 and a data bus 122. Address bus 120 allows individual memory locations within memory 104 to be accessed by processing unit 102. Data bus 122 is used to pass data between processing unit 102 and memory 104.

As shown in FIG. 1, processing unit 102 includes an execution unit 106 and an address generator 110. Execution unit 106 includes a plurality of execution registers 108. Address generator 110 includes a plurality of address registers 112. Execution registers 108 and address registers 112 are used, for example, to read and store temporary variable and/or address data.

Memory 104 typically includes both read-only memory (ROM) and random-access memory (RAM). Memory 104 is depicted in FIG. 1 as including a ROM memory segment 114, a RAM-1 memory segment 116, and a RAM-2 memory segment 118. These memory segments are illustrative only, and they are not intended to limit the present invention.

In operation, one of a plurality of operating instructions is retrieved, for example, from RAM-1 memory segment 116 and acted upon by execution unit 106. Typically, a retrieved instruction will involve moving data from one memory location to another memory location or performing an arithmetic operation on data located in one or more memory locations. Address generator 110 is used to determine the type of addressing used within an operating instruction and generate an appropriate address. How this is accomplished is described in more detail below.

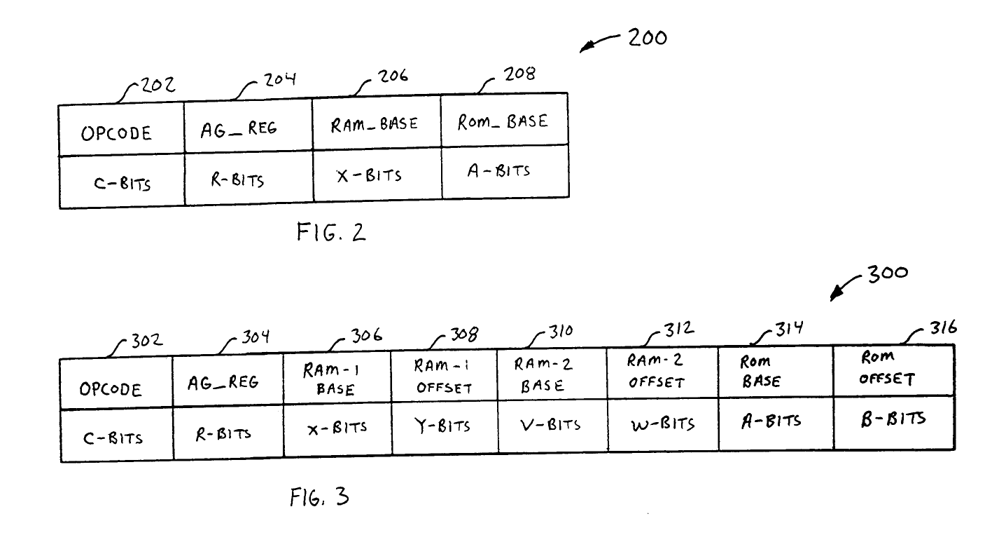

FIG. 2 illustrates an example instruction format or instruction 200 for digital signal processor 100. Instruction 200 includes four fields or instruction segments 202, 204, 206, and 208. Other fields or instruction segments can also be added without deviating from the present invention. Instruction 200 is used to load address data, for example, for variables into address registers 112.

Instruction segment 202 is a c-bit instruction segment (OPCODE), wherein the number of bits (c) of instruction segment 202 is selected based on, for example, the total number of instructions associated with digital signal processor 100. The bits of instruction segment 202 are decoded and appropriately acted upon by execution unit 106.

Instruction segment 204 is an r-bit instruction segment (AG_REG), wherein the number of bits (r) of instruction segment 204 is selected based on, for example, the total number of address registers 112. The bits of instruction segment 204 are used to specify one of the plurality of address registers 112 used to store address data for accessing a particular memory location in ROM memory segment 114, RAM-1 memory segment 116, or RAM-2 memory segment 118.

Instruction segment 206 is an x-bit instruction segment (RAM_BASE), wherein the number of bits (x) of instruction segment 206 is selected based on, for example, the total amount of addressable RAM memory. The bits of instruction segment 206 are used to specify a base address for data stored in a particular memory location in RAM-1 memory segment 116 or RAM-2 memory segment 118.

Instruction segment 208 is an a-bit instruction segment (ROM_BASE), wherein the number of bits (a) of instruction segment 208 is selected based on, for example, the total amount of addressable ROM memory. The bits of instruction segment 208 are used to specify a base address for data stored in a particular memory location in ROM memory segment 114.

FIG. 3 illustrates a second example instruction format or instruction 300 for digital signal processor 100. Instruction 300 includes eight fields or instruction segments 302, 304, 306, 308, 310, 312, 314, and 316. As with instruction 200, other fields or instruction segments can also be added without deviating from the present invention. Instruction 300 is used to load address data, for example, for variables into address registers 112.

Instruction segment 302 is a c-bit instruction segment (OPCODE), wherein the number of bits (c) of instruction segment 302 is selected based on, for example, the total number of instructions associated with digital signal processor 100. The bits of instruction segment 302 are decoded and appropriately acted upon by execution unit 106.

Instruction segment 304 is an r-bit instruction segment (AG_REG), wherein the number of bits (r) of instruction segment 304 is selected based on, for example, the total number of address registers 112. The bits of instruction segment 304 are used to specify one of the plurality of address registers 112 used to store address data for accessing a particular memory location in ROM memory segment 114, RAM-1 memory segment 116, or RAM-2 memory segment 118.

Instruction segment 306 is an x-bit instruction segment (RAM-1 BASE), wherein the number of bits (x) of instruction segment 306 is selected based on, for example, the total amount of addressable RAM-1 memory. The bits of instruction segment 306 are used to specify a base address for data stored in a particular memory location in RAM-1 memory segment 116.

Instruction segment 308 is a y-bit instruction segment (RAM-1 OFFSET), wherein the number of bits (y) of instruction segment 308 is a design option. The bits of instruction segment 308 are used to specify an address offset that is added to the RAM-1 base address for addressing data stored in a particular memory location in RAM-1 memory segment 116.

Instruction segment 310 is an v-bit instruction segment (RAM-2 BASE), wherein the number of bits (v) of instruction segment 310 is selected based on, for example, the total amount of addressable RAM-2 memory. The bits of instruction segment 310 are used to specify a base address for data stored in a particular memory location in RAM-2 memory segment 118.

Instruction segment 312 is a w-bit instruction segment (RAM-2 OFFSET), wherein the number of bits (w) of instruction segment 312 is a design option. The bits of instruction segment 312 are used to specify an address offset that is added to the RAM-2 base address for addressing data stored in a particular memory location in RAM-2 memory segment 118.

Instruction segment 314 is an a-bit instruction segment (ROM BASE), wherein the number of bits (a) of instruction segment 314 is selected based on, for example, the total amount of addressable ROM memory. The bits of instruction segment 314 are used to specify a base address for data stored in a particular memory location in ROM memory segment 114.

Instruction segment 316 is a b-bit instruction segment (ROM OFFSET), wherein the number of bits (b) of instruction segment 316 is a design option. The bits of instruction segment 316 are used to specify an address offset that is added to the ROM base address for addressing data stored in a particular memory location in ROM memory segment 114.

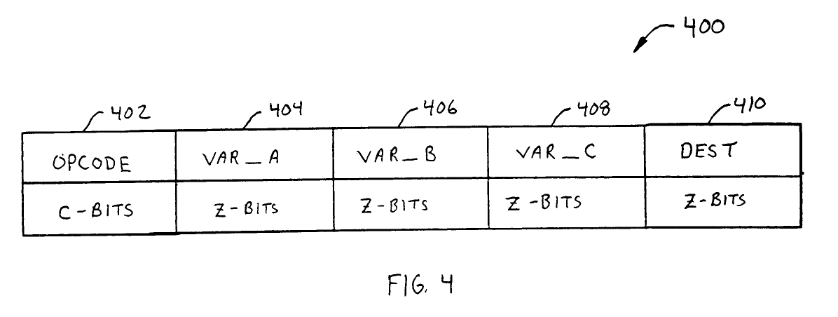

FIG. 4 illustrates a third example instruction format or instruction 400 for digital signal processor 100. Instruction 400 includes five fields or instruction segments 402, 404, 406, 408, and 410. Other fields or instruction segments can also be added without deviating from the present invention. Instruction 400 is used to perform arithmetic operations.

Instruction segment 402 is a c-bit instruction segment (OPCODE), wherein the number of bits (c) of instruction segment 402 is selected based on, for example, the total number of instructions associated with digital signal processor 100. Instruction segment 402 specifies one or more particular arithmetic operations to be performed on one or more variables. The bits of instruction segment 402 are decoded and appropriately acted upon by execution unit 106.

Instruction segments 404, 406, and 408 are used to specify the addresses of up to three variables that are to be operated upon arithmetically in accordance with instruction segment 402. Each instruction segment 404, 406 and 408 comprises z-bits. Of these z-bits, one or more of them are used to designate a particular type of addressing to be used to access the variables. For example, the first two bits of each instruction segment 404, 406 and 408 can be used to designate that indirect addressing, register addressing, or immediate addressing is to be used to access the variables. If, for example, only two of these types of addressing are permitted, than only one of the z-bits in each instruction segment 404, 406 and 408 is needed to specify which of the two types of permitted addressing is to be used to access the variables. The bits not used to designate the type of addressing to be used to access the variables comprise address data.

Instruction segment 410 specifies where the result of instruction 400 is stored. Like the instruction segments 404, 406 and 408, instruction segment 410 comprises z-bits. One or more of these z-bits are used to designate the particular type of addressing to be used. The bits not used to designate the type of addressing to be used comprise address data.

Address generator 110 interprets the z-bits of each instruction segment 404, 406, 408, and 410 to generate an appropriate address for accessing a variable or storing the result of instruction 400. Because the bits used to specify the types of addressing to be used are part of the programmable instruction segments 404, 406, 408, and 410, rather than the OPCODE instruction segment 402, a single instruction according to the present invention is capable of performing more than one type of addressing. For example, a single instruction 400 can perform concurrently indirect addressing, register addressing, and/or immediate addressing on a variable-by-variable basis. This enhanced feature of the present invention permits address generator 110 to be flexibly programmed.

Example Decoder Application According to the Present Invention

The features and advantages of the digital signal processor of the present invention will now be described in greater detail by way of an example decoder application.

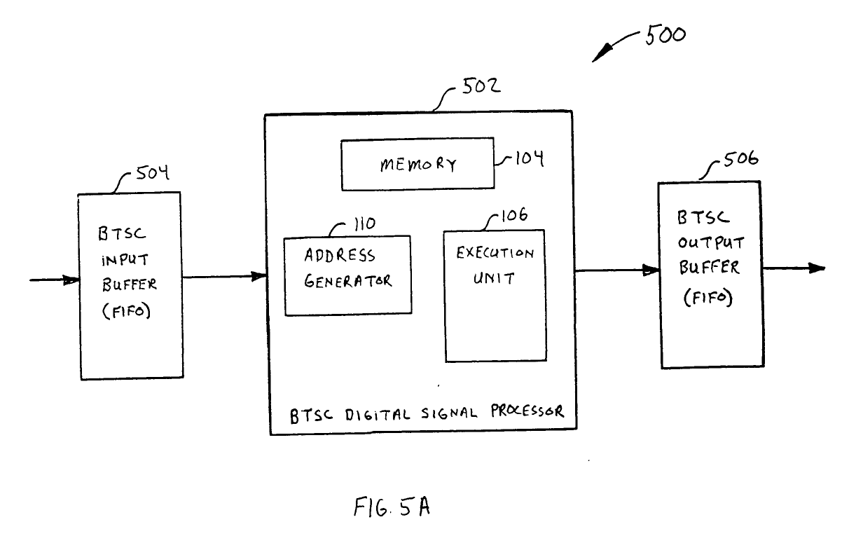

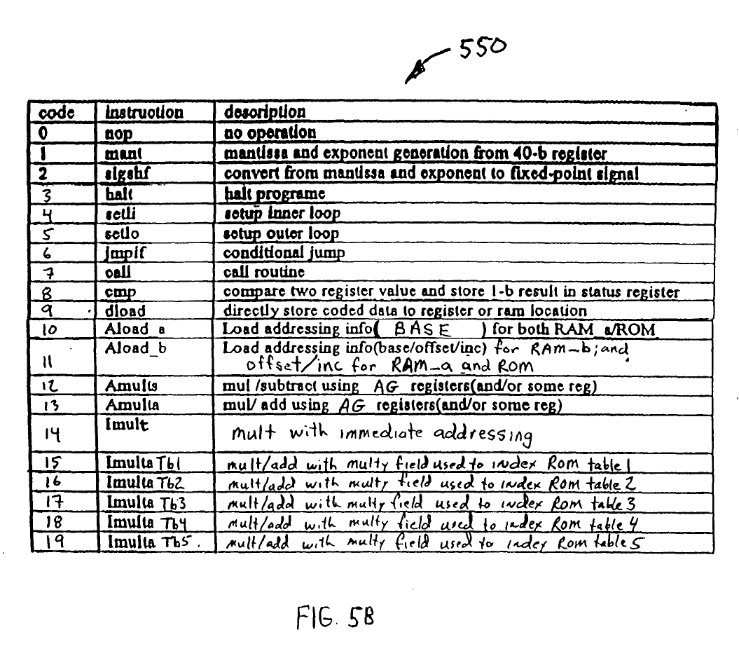

FIG. 5A illustrates a BTSC decoder 500 that uses a digital signal processor 502 according to the present invention. As illustrated in FIG. 5, BTSC decoder 500 includes a BSTC digital signal processor 502, a BTSC input buffer 504, and a BTSC output buffer 506. BSTC digital signal processor 502 includes a memory 104, an execution unit 106 having execution registers 108 (not shown), and an address generator 110 having address registers 112 (not shown). BTSC input buffer 504 and BTSC output buffer 506 are first-in-first-out (FIFO) buffers.

In an embodiment, BTSC decoder 500 forms part of a television on a chip integrated circuit.

BTSC decoder 500 and/or BSTC digital signal processor 502 are capable of decoding both US and Japan BTSC signals. This is achieved by running a program code on BTSC decoder 500 that can flexibly access appropriate variable data needed for decoding both US and Japan BTSC signals. When decoding US BTSC signals, the program code running on BTSC decoder 500 use arithmetic instructions having flexible, programmable addressing capabilities to access the particular data needed to decode US BTSC signals. Similarly, when decoding Japan BTSC signals, the program running on BTSC decoder 500 uses the arithmetic instructions having flexible, programmable addressing capabilities to access the particular data needed to decode Japan BTSC signals. The variable data needed to decode US and Japan BTSC signals can be stored in read-only memory and/or random-access memory. As would be known to persons skilled in the relevant art, variable data needed to decode US or Japan BTSC signals, as appropriate, can be downloaded to random-access memory and/or register memory, if need be, prior to running a BTSC decoding algorithm. How to program BTSC decoder 500 and/or BSTC digital signal processor 502 using supported instructions to implement a BTSC decoding algorithm will become apparent to persons skilled in the relevant art given the description herein.

Generally speaking, in operation, BTSC decoder 500 receives BTSC signal input data. This input data is temporarily stored in BTSC input buffer 504. Input data stored in BTSC input buffer 504 is operated upon on a FIFO basis by execution unit 106 in accordance with a BTSC decoding program and variable data stored, for example, in memory 104. As would be known to persons skilled in the relevant arts, a BTSC decoding algorithm is implemented using digital filters such as a first-order infinite impulse response (IIR) filter and a second-order IIR filter. Address generator 110 calculates addresses, for example, for the appropriate variable decoding data used by the BTSC decoding algorithm and the IIR filters based on address information stored in address registers 112 and address information stored in variable fields of arithmetic instructions according to the present invention. How this is accomplished is described in more detail below. The output of BTSC digital signal processor 502 is stored in BTSC output buffer 506 on a FIFO basis.

As described herein, a BTSC algorithm running on BTSC decoder 500 is used to decode received BTSC signals. This algorithm is implemented using instructions of the BTSC decoder instruction set. An example instruction set for BTSC decoder 500 and/or BTSC digital signal processor 502 is described below.

Example Instruction Set

FIG. 5B illustrates an example instruction set 550 for BTSC decoder 500 and/or BSTC digital signal processor 502. Instruction set 550 includes both address register load instructions and arithmetic instructions according to the present invention. As illustrated in FIG. 5B, instruction set 550 comprises twenty supported instructions. Additional instructions can be added to instruction set 550 and supported by BTSC decoder 500 in order to add additional functionality to BTSC decoder 500, if desired. Example instruction set 550 and the descriptions of these instructions that follow are intended to illustrate only a specific embodiment of the present invention and not to limit the present invention.

Instruction 0 (nop) performs no operation. This instruction is useful, for example, for inserting cycle delays into a program code intended to be executed by BTSC digital signal processor 502.

Instruction 1 (mant) converts a fixed-point formatted signal or value into a mantissa and exponent formatted signal or value. In an embodiment, the fixed-point formatted signal or value is represented by 40 bits.

Instruction 2 (sigshf) converts a mantissa and exponent formatted signal or value into a fixed-point formatted signal or value.

Instruction 3 (halt) halts the operation of a program code being executed by BTSC digital signal processor 502.

Instruction 4 (setli) sets up an inner loop of a program code being executed by BTSC digital signal processor 502.

Instruction 5 (setlo) sets up an outer loop of a program code being executed by BTSC digital signal processor 502.

Instruction 6 (jmpif) performs a conditional jump to a designated portion of a program code being executed by BTSC digital signal processor 502.

Instruction 7 (call) is used to call a program code routine.

Instruction 8 (cmp) compares two register values and stores a one-bit result in a status register.

Instruction 9 (dload) is used to directly store coded data in a register or RAM memory location.

Instruction 10 (Aload_a) loads addressing information (base/offset/inc) for RAM and ROM memory into address registers 112.

Instruction 11 (Aload_b) loads addressing information (base/offset/inc) for RAM memory into address registers 112. Instruction 11 also loads the offset/inc information for instruction 10.

Instruction 12 (Amults) performs a multiplication of selected values and then subtracts the result from a selected value. Instruction 12 uses the address registers 112 and/or execution registers 108 as described herein to access data.

Instruction 13 (Amulta) performs a multiplication of selected values and then adds the result to a selected value. Instruction 13 also uses the address registers 112 and/or execution registers 108 as described herein to access data.

Instruction 14 (Imult) performs a multiplication of selected values.

Instruction 15 (ImultaTb1) performs a multiplication of selected values and then adds the result to a selected value. Instruction 15 differs from instruction 14 in that one of its variable fields (multy) is used to index a special ROM lookup table 1.

Instruction 16 (ImultaTb2) performs a multiplication of selected values and then adds the result to a selected value. Instruction 16 uses one of its variable fields (multy) to index a special ROM lookup table 2.

Instruction 17 (ImultaTb3) performs a multiplication of selected values and then adds the result to a selected value. Instruction 17 uses one of its variable fields (multy) to index a special ROM lookup table 3.

Instruction 18 (ImultaTb4) performs a multiplication of selected values and then adds the result to a selected value. Instruction 18 uses one of its variable fields (multy) to index a special ROM lookup table 4.

Instruction 19 (ImultaTb5) performs a multiplication of selected values and then adds the result to a selected value. Instruction 19 uses one of its variable fields (multy) to index a special ROM lookup table 5.

As noted above, additional instructions can be added to instruction set 550 in order to add additional functionality to BTSC decoder 500 and/or BSTC digital signal processor 502.

Address Register Load Instructions and Arithmetic Instructions

As noted herein, the instructions of instruction set 550 permit BTSC decoder 500 to decode both US and Japan BTSC signals. This is accomplished by running a BTSC decoder algorithm on BTSC decoder 500. As would be known to persons skilled in the relevant arts, a BTSC decoder algorithm functions by continuously performing a series of multiply and accumulate operations on the received BTSC signal data. The BTSC decoder algorithm is controlled using appropriate loop controls and conditional jump and conditional call programming techniques supported by instruction set 550.

To better appreciate features and advantages of the present invention, it is useful to consider how address register load instructions 10 and 11 are used in conjunction with arithmetic instructions of the present invention to implement a first-order IIR filter and a second-order IIR filter.

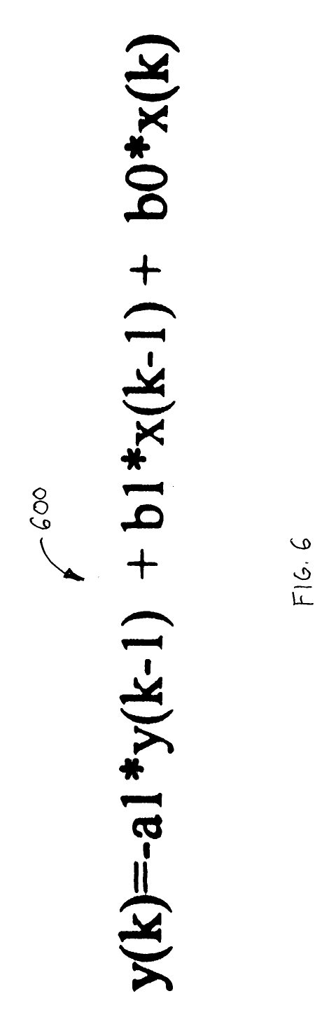

FIG. 6 illustrates an equation 600 that represents the operation of a first-order IIR filter. The filtering operation represented by equation 600 is used to implement the BTSC decoding algorithm. As can be seen by examining equation 600, the filter operates as follows. The last output of the filter, y(k−1), is multiplied by a variable (coefficient), a1, and the result is subtracted from zero to form an accumulation value. The present BTSC input sample, x(k), is multiplied by a variable, b0, and the result added to the accumulation value to form a two-term accumulation value. The immediately proceeding BTSC input sample, x(k−1), is multiplied by a variable, b1, and the result is added to the two-term accumulation value to from the filter output, y(k). As will be understood by a person skilled in the relevant art, the order of these three multiply and accumulate operations is unimportant to the proper operation of the filter. The values of the variables a1, b0, and b1 are dependent upon the BTSC signal being decoded.

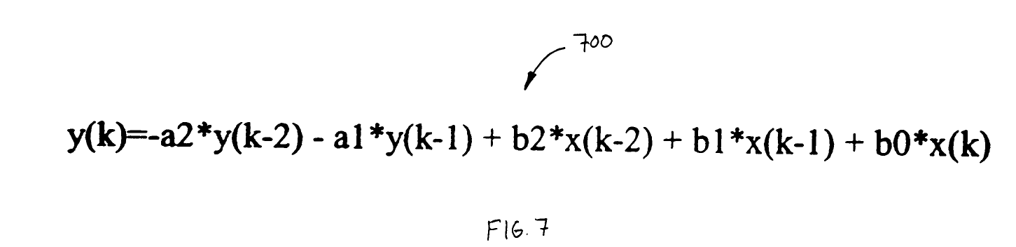

FIG. 7 illustrates an equation 700 that represents the operation of a second-order IIR filter. The filtering operation represented by equation 700 is also used to implement the BTSC decoding algorithm. As can be seen by examining equation 700, the filter operates as follows. The last output of the filter, y(k−1), is multiplied by the variable, a1, and the result is subtracted from zero to form an accumulation value. The next to the last output, y(k−2), is multiplied by a variable, a2, and the result added to the accumulation value to form a two-term accumulation value. The present BTSC input sample, x(k), is multiplied by the variable, b0, and the result added to the two-term accumulation value to form a three-term accumulation value. The immediately proceeding BTSC input sample, x(k−1), is multiplied by the variable, b1, and the result is added to the three-term accumulation value to from a four-term accumulation value. The BTSC input sample, x(k−2), is multiplied by a variable, b2, and the result is added to the four-term accumulation value to from the filter output, y(k). As with the first-order IIR filter, the order of these five multiply and accumulate operations is unimportant to the proper operation of the filter represented by equation 700. The value of each of the variables a0, a1, b0, b1, and b2 is dependent upon the BTSC signal being decoded.

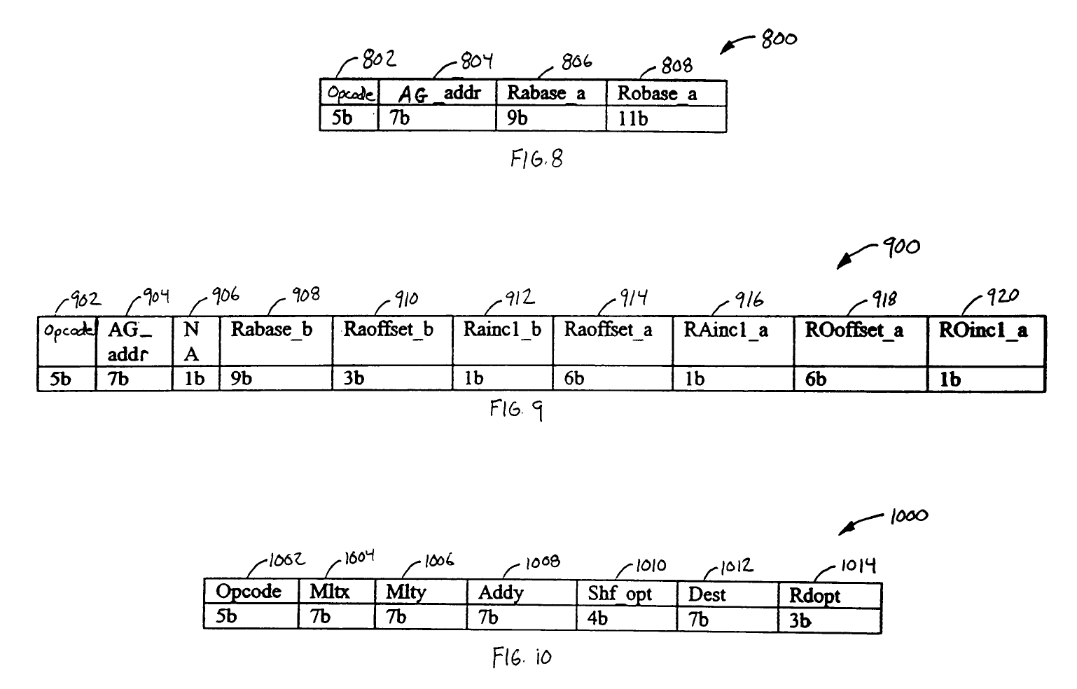

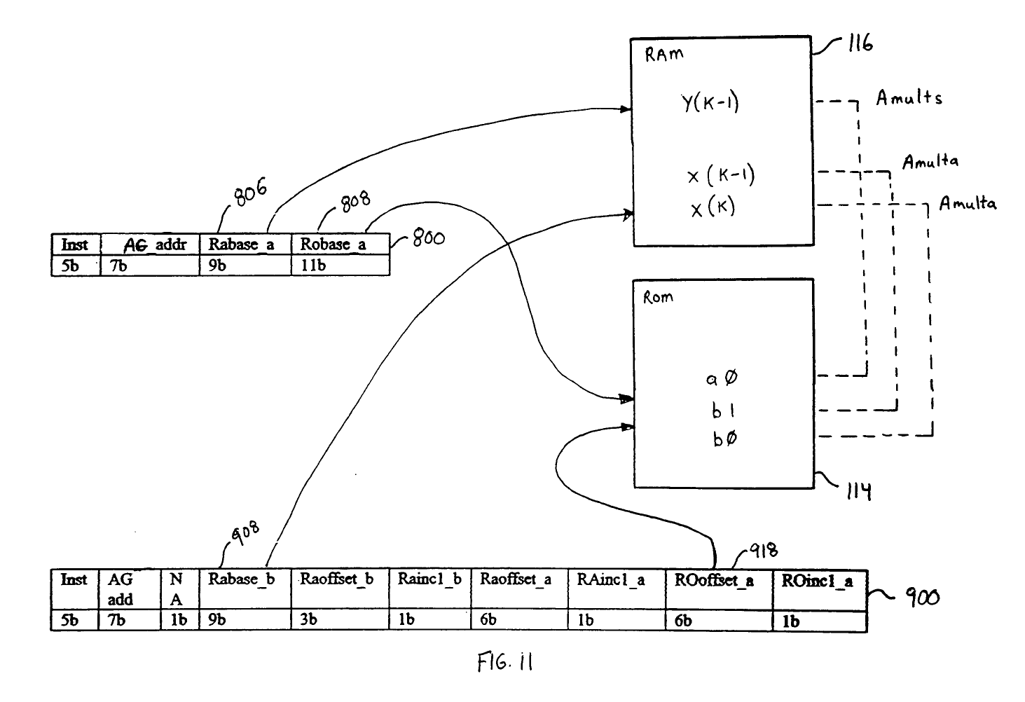

Generally speaking, the filters represented by equation 600 and equation 700 are implemented by BTSC decoder 500 by executing a series of multiply and accumulate instructions. Two arithmetic instructions of instruction set 550 designed to performing these arithmetic operations are instruction 12 (Amults) and instruction 13 (Amulta). The format of these instructions is described below with regard to FIG. 10. Prior to executing instructions 12 and 13, instruction 10 (Aload_a) and instruction 11 (Aload_b) of instruction set 550 are used to load addressing information needed by instructions 12 and 13 into address registers 112. This ensures that the proper values, for example, for the variables a0, a1, b0, b1, and b2 are used to decode the BTSC signal being received by BTSC decoder 500. The formats of instructions 11 and 12 are described below with regard to FIG. 8 and FIG. 9, respectively. Instructions 17-21 are used, when needed, to address values stored in special ROM lookup tables. The format of these instructions is illustrated by FIG. 10.

FIG. 8 illustrates an example instruction format or instruction 800 used with BTSC decoder 500. As illustrated in FIG. 8, instruction 800 has four fields 802, 804, 806, and 808. Instruction 800 is used, for example, for loading or storing addressing information into address registers 112 prior to executing an arithmetic instruction. Instruction format 800 is the format used for instruction 10 (Aload_a) of instruction set 550. As described below, instruction 800 (e.g., instruction 10 (Aload_a) of instruction set 550) is used in conjunction with fields 914, 916, 918, and 920 of instruction 900 (e.g., instruction 11 (Aload_b) of instruction set 550).

Field 802 (OPCODE) is the opcode field. Field 802 contains control bits used to control the operation of execution unit 106. In an embodiment, field 802 contains five control bits. The number of control bits is based, for example, on the total number of instruction implemented by BTSC decoder 500.

Field 804 (AG_ADDR) of instruction 800 is an address register designation field. Field 804 is used to specify, for example, one of the address registers 112, which can be used to hold indirect addressing mode address information for RAM-1, RAM-2, and/or ROM. In an embodiment, field 804 contains seven bits and is of the form (00xxxxx). The five variable bits of field 804 are used to designate one of 32 address registers.

Field 806 (RABASE_A) of instruction 800 is a RAM base address designation field. In an embodiment, field 806 contains nine bits used to designate/store a base address for operands such as, for example, the output values Y in equation 600 or equation 700.

Field 808 (ROBASE_A) of instruction 800 is a ROM base address designation field. In an embodiment, field 806 contains eleven bits used to designate/store a ROM base address. Field 808 is used to designate/store a base address for operands stored in ROM.

FIG. 9 illustrates an example instruction format or instruction 900 used with BTSC decoder 500. Instruction 900 has ten fields 902, 904, 906, 908, 910, 912, 914, 916, 918, and 920. Instruction 900 is used, for example, for loading or storing addressing information into address registers 112 prior to executing an arithmetic instruction. Instruction format 900 is the format used for instruction 11 (Aload_b) of instruction set 550. In the embodiment illustrated in FIG. 9, instruction 900 has forty bits.

Field 902 (OPCODE) is the opcode field. Field 902 contains control bits used to control the operation of execution unit 106. In an embodiment, field 902 contains five control bits.

Field 904 (AG_ADDR) of instruction 800 is an address register designation field. Field 904 is used to specify, for example, one of the address registers 112, which can be used to hold indirect addressing mode address information for RAM-1, RAM-2, and/or ROM. In an embodiment, field 904 contains seven bits and is of the form (00xxxxx). The five variable bits of field 904 are used to designate one of 32 address registers.

Field 906 is a non-applicable field containing one bit, which results from the fact that, in an embodiment, instruction 900 contains forty bits. As illustrated by field 906, not every bit of an instruction according to the present invention must be used.

Field 908 (RABASE_B) of instruction 900 is a RAM base address designation field. In an embodiment, field 908 contains nine bits used to designate/store a base address for operands such as, for example, the input values X in equation 600 or equation 700.

Field 910 (RAOFFSET_B) of instruction 900 is a RAM offset address designation field. In an embodiment, field 910 contains three bits used to designate/store an offset value that is added to the value of field 908 of instruction 900 to obtain the address of an operand.

Field 912 (RAINC1_B) of instruction 900 is a post-increment/post-decrement designation field. In an embodiment, field 912 contains one bit. If this bit is a one, the offset value of field 910 is incremented by one each time the address register specified by field 904 is referenced in an operand field of an arithmetic instruction. If the bit in field 912 is a zero bit, the offset value of field 910 is decremented by one each time the address register specified by field 904 is referenced in an operand field of an arithmetic instruction. In an embodiment, field 912 contains more than one bit in order to allow, for example, for post-incrementing and/or post-decrementing by two, which is used in BTSC decoding when down-sampling by two (e.g., US BTSC decimation from 10X to 5X). In the embodiment shown in FIG. 9, down-sampling by two is accomplished using a special address register ASOS5XB12, which is described below, rather than post-incrementing and/or post-decrementing by two because it can avoid longer delays associated with post-incrementing and/or post-decrementing by two.

Field 914 (RAOFFSET_A) of instruction 900 is a RAM offset address designation field. In an embodiment, field 914 contains six bits used to designate/store an offset value that is added to the value of field 806 of instruction 800 to obtain the address of an operand.

Field 916 (RAINC1_A) of instruction 900 is a post-increment/post-decrement designation field. Field 916 is similar to field 912. In an embodiment, field 916 contains one bit. If this bit is a one, the offset value of field 914 of instruction 900 is incremented by one, for example, each time the address register specified by field 804 is referenced in an operand field of an arithmetic instruction. If the bit in field 916 is a zero bit, the offset value of field 914 is decremented by one each time the address register specified by field 804 is referenced in an operand field of an arithmetic instruction. In other embodiments, field 916 contains more than one bit for the reason noted above with regard to field 912.

Field 918 (ROOFFSET_A) of instruction 900 is a ROM offset address designation field. In an embodiment, field 918 contains six bits used to designate/store an offset value that is added to the value of field 808 of instruction 800 to obtain the address of an operand.

Field 920 (ROINC1_A) of instruction 900 is a post-increment/post-decrement designation field. Field 920 is similar to fields 912 and 916. In an embodiment, field 920 contains one bit. If this bit is a one, the offset value of field 918 of instruction 900 is incremented by one, for example, each time the address register specified by field 804 is referenced in an operand field of an arithmetic instruction. If the bit in field 920 is a zero bit, the offset value of field 918 is decremented by one each time the address register specified by field 804 is referenced in an operand field of an arithmetic instruction. In other embodiments, field 920 contains more than one bit for the reason noted above with regard to field 912.

FIG. 10 illustrates an example instruction format or instruction 1000 used with BTSC decoder 500. Instruction 1000 includes seven fields 1002, 1004, 1006, 1008, 1010, 1012, and 1014. Instruction 1000 is used, for example, for performing arithmetic operations such as, for example, multiply-add arithmetic or multiply-subtract arithmetic on variable data. Instruction format 1000 is used, for example, for instructions 12-19 of instruction set 550.

Field 1002 (OPCODE) is the opcode field. Field 1002 contains control bits used to control the operation of execution unit 106. In an embodiment, field 1002 contains five control bits.

The four fields 1004 (MLTX), 1006 (MLTY), 1008 (ADDY), and 1012 (DEST) are operand designation fields. These fields allow a programmer to program both the type of addressing mode to be used and the particular address information for an operand. The fields 1004, 1006, 1008, and 1012 can contain mixed addressing mode information, i.e., each of these fields for a single instruction is not required to contain or use the same type of addressing mode.

In an embodiment, each of the four fields 1004, 1006, 1008, and 1012 contains seven bits. These seven bits are encoded as follows with regard, for example, to instruction 12 (Amults) and instruction 13 (Amulta) of instruction set 550.

For indirect addressing, in an embodiment, the fields 1004, 1006, 1008, and 1012 have the form (11xxxxx). The first two bits (11) designate indirect addressing mode. This mode is used to access operands stored in RAM or ROM. The five variable bits of fields 1004, 1006, 1008, and 1012 designate with of the address registers 112 contain the addressing information. As noted herein, instruction 10 (Aload_a) and instruction 11 (Aload_b) precede instruction 12 (Amults) and instruction 13 (Amulta) of instruction set 550 in order to preload read/write RAM/ROM addressing information into address registers 112. The addresses for operands that are addressed using indirect addressing mode are computed using base-plus-offset information. The offset is determined from moduloX(buffer_countX_Y+post_inc/dec (AdressGenerator_offsetA_B)). The address generator register name specifies which X, Y, and address generator offset is used in the offset computation.

For register addressing, in an embodiment, the fields 1004, 1006, 1008, and 1012 have the form (10xxxxx). The first two bits (10) designate register addressing mode. The five variable bits designate one of thirty-two data registers. The names rega, regb, regc, et cetera can be used during programming to designate these registers.

For immediate addressing, in an embodiment, the fields 1004, 1006, 1008, and 1012 have the form (01xxxxx). The first two bits (01) designate immediate addressing mode. In immediate addressing mode, the address is the combination of the seven bits of field 1008 (ADDY) concatenated to the five variable bits (i.e., {ADDY,xxxxx}). When using immediate addressing mode, field 1008 is used as the page address. Field 1008 cannot be used for immediate addressing. Fields 1004, 1006, and 1012 can be used for immediate addressing with the limitation that the addresses use the same page (i.e., the bits of field 1008).

Field 1010 of instruction 1000 is a shift designation field. It is used, for example, to shift the contents of the product before adding.

Field 1014 of instruction 1000 is a optional rounding designation field. It is used to designate a type of rounding to be applied to the destination operand.

During programming of BTSC decoder 500, it is useful to use different operand naming techniques to distinguish the different possible addressing modes. For example, for register addressing mode, regx can be used to indicate that register addressing mode is being used. For immediate addressing, ram_xxx and rom_xxx can be used to indicate that immediate addressing mode is being used. Finally, an all CAPITAL name can be used with indirect addressing to indicate the use of indirect addressing mode. Other naming conventions, however, can also be used.

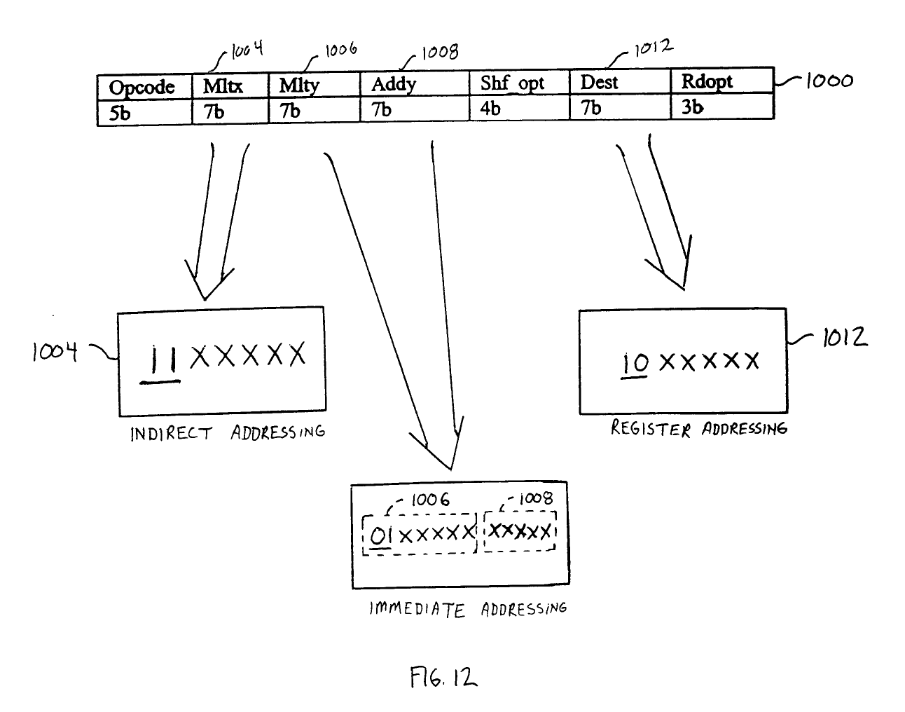

FIG. 11 illustrates the operation of selected fields of instruction 800 and instruction 900. As shown in FIG. 11, instruction 800 and instruction 900 are used in conjunction to specify/store addressing information for variables/operands. Field 806 of instruction 800 specifies the base memory location of variable/operand y(k−1) in RAM 116. Field 808 of instruction 800 specifies the base memory location of variable/operand a0 in ROM 114. Field 908 of instruction 900 specifies the base memory location of variable/operand x(k) in RAM 116. Field 918 of instruction 900 specifies the offset to be used with field 808 to access variable/operand b1 in ROM 114.

As described herein, and illustrated in FIG. 11, the filter represented by equation 600 can be implemented using three multiply and accumulate arithmetic operations. More particularly, as shown in FIG. 11, one Amults and two Amulta instructions of instruction set 550 can be used to implement the first-order IIR filter represented by equation 600.

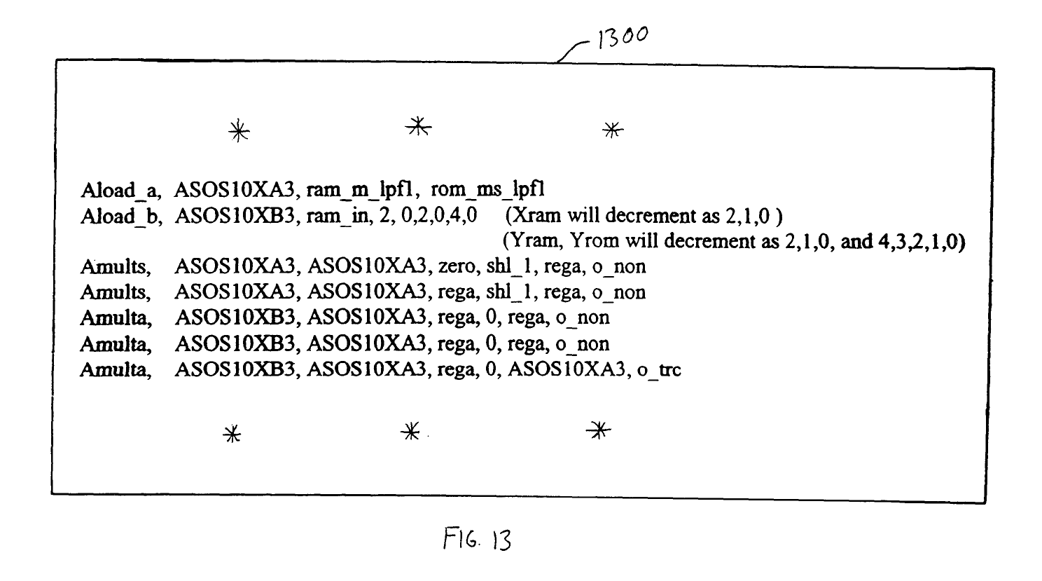

FIG. 12 illustrates the operation of an instruction 1000. As shown in FIG. 12, a single instruction such as, for example, instruction 12 (Amults) or instruction 13 (Amulta) according to the present invention can use more than one type of addressing mode.

Address Registers

Due to the different decimation rates in the US BTSC standard (10X, 5X, and 1X) and the Japan BTSC standard (8X and 1X), and the various buffer lengths (modulo) for different filters, various address registers are used in BTSC decoder 500. For example, for a 10X loop, registers ASOS10XA3, ASOS10XB3, AFOS10XA2, AFOS10XA10, AFOS10XA12, and ABPF10X41 are used.

Registers ASOS10XA3 and ASOS10XB3 are used to implement the filter represented by equation 700. These two registers are modulo 3 registers. They use a buffer_count3_{—}10X counter that is updated every time the setlo 10X loop returns. The initial A in the name of the above two registers indicates address register. The SOS in the name of the above two registers indicates a second-order filter. The 10X in the names indicates a rate of 10X. The A3 and B3 in the names indicates the a's and b's modulo 3 in equation 700.

Registers AFOS10XA2, AFOS10XA10, AFOS10XA12 are used to implement the filter represented by equation 600. Register AFOS10XA2 is a modulo 2 register that uses a buffer_count2_{—}10X counter that is updated every time the setlo 10X loop returns. The initial A in the name of the register indicates address register. The FOS in the name of the register indicates a first-order filter. The 10X in the names indicates a rate of 10X. The A2 in the name indicates the a's modulo 2 in equation 600. Registers AFOS10XA10 and AFOS10XA12 are modulo 10 and 12 registers. They use a buffer_count10_{—}10X counter and a buffer_count12_{—}10X counter, respectively, that is updated every time the setlo 10X loop returns.

Register ABPF10X41 is used to implement a band pass filter.

The registers ASOS5XA3, ASOS5XB12, ASOS5XB3, AFOS5XA2, AFOS5XB2, ARMS5X3, ARMS5X4, and A5X5 are used for 5X loops. The RMS in the name indicates RMS filter. The buffer counter for each register is determined as noted above (e.g., the buffer counter for ASOS5XA3 is buffer_count3_{—}5X).

The registers ASOS1XA3, ASOS1XB3, AFOS1XA2, AFOS1XB2, AFOS2_{—}1XA2, ASRC1XL1, ASRCLXR1, ASRC1XL1L2, and ASRC1XR1R2 are used for 1X loops. The R and L indicate left and right channels.

The registers A8XA65, A8XA43, A8XA32, and ADIRECT are used for 8X loops (i.e., Japan BTSC standard). The buffer counter for each register is determined as noted herein (e.g., the buffer counter for A8XA65 is buffer_count65_{—}8X). ADIRECT is a dummy register used when the offset is zero.

FIG. 13 illustrates an example program code segment 1300 for BTSC decoder 500. Program code segment 1300 is written using instruction set 550. Program code segment 1300 implements the second-order IIR filter represented by equation 700. The operation of program code segment 1300 will become apparent to persons skilled in the relevant arts given the description herein.

Based on the description herein, how to program BTSC decoder 500 and digital signal processor 502 to implement a BTSC decoder algorithm and decode a BTSC signal will become apparent to persons skilled in the relevant arts.

### CONCLUSION

While various embodiments of the present invention have been described above, it should be understood that they have been presented by way of example only, and not limitation. It will be understood by those skilled in the art that various changes in form and details may be made therein without departing from the spirit and scope of the invention as defined in the appended claims. Thus, the breadth and scope of the present invention should not be limited by any of the above-described exemplary embodiments, but should be defined only in accordance with the following claims and their equivalents.

1. A digital signal processor, comprising:
an execution unit that executes a plurality of instructions;
a plurality of registers coupled to said execution unit;
a programmable address generator coupled to said execution unit; and
a memory coupled to said programmable address generator and said execution unit,
wherein said programmable address generator enables said execution unit to perform register addressing, indirect addressing, and immediate addressing in response to an arithmetic instruction of the plurality of instructions.

2. The digital signal processor of claim 1, wherein said memory comprises random-access memory and read-only memory.

3. The digital signal processor of claim 2, wherein said plurality of registers comprises execution registers and address registers.

4. The digital signal processor of claim 3, wherein said address registers comprise a register for storing a random-access memory base address value.

5. The digital signal processor of claim 4, wherein said address registers comprise a register for storing a random-access memory offset address value.

6. The digital signal processor of claim 3, wherein said address registers comprise a register for storing a read-only memory base address value.

7. The digital signal processor of claim 6, wherein said address registers comprise a register for storing a read-only memory offset address value.

8. The digital signal processor of claim 1, wherein said arithmetic instruction performs multiplication and subtraction.

9. The digital signal processor of claim 1, wherein said arithmetic instruction indexes a lookup table.

10. A BTSC decoder, comprising:
an execution unit that executes a plurality of instructions;
a plurality of registers coupled to said execution unit;
a programmable address generator coupled to said execution unit; and
a memory coupled to said programmable address generator and said execution unit,
wherein said programmable address generator enables said execution unit to perform register addressing, indirect addressing, and immediate addressing in response to the plurality of instructions.

11. The BTSC decoder of claim 10, wherein the register addressing, indirect addressing, and immediate addressing are performed in response to an arithmetic instruction of the plurality of instructions.

12. The BTSC decoder of claim 11, wherein said memory comprises random-access memory and read-only memory.

13. The BTSC decoder of claim 12, wherein said plurality of registers comprises execution registers and address registers.

14. The BTSC decoder of claim 13, wherein said address registers comprise a register for storing a random-access memory base address value.

15. The BTSC decoder of claim 14, wherein said address registers comprise a register for storing a random-access memory offset address value.

16. The BTSC decoder of claim 13, wherein said address registers comprise a register for storing a read-only memory base address value.

17. The BTSC decoder of claim 16, wherein said address registers comprise a register for storing a read-only memory offset address value.

18. The BTSC decoder of claim 11, wherein said arithmetic instruction performs multiplication and subtraction.
